(19) United States
(12) Patent Application Publication
(10) Pub. No.: US 2003/0222693 A1
(43) Pub. Date: Dec. 4, 2003

(54) Variable delay generator

(76) Inventors: Shai Cohen, Haifa (IL); Ronnen Lovinger, Ra'anana (IL)

Correspondence Address: WOODCOCK WASHBURN LLP, ONE LIBERTY PLACE, 46TH FLOOR, 1650 MARKET STREET, PHILADELPHIA, PA, 19103, US

(21) Appl. No.: 10/169,261

(22) PCT Filed: Dec. 28, 2000
(86) PCT No.: PCT/IL00/00868

(51) Int. Cl. H03H 11/26

(52) U.S. Cl. 327/277

(57) ABSTRACT

Apparatus (28) for applying a delay to an input signal (50) includes a plurality of delay devices (40), each having an input and an output, coupled in series such that the output of each of the delay devices, except for a final delay device (51) in the series, is coupled to the input of a succeeding one of the delay devices in the series. A switching unit (34) is adapted to receive a delay selection signal indicative of a desired time delay and, responsive thereto, to couple the input signal to the input of a designated one of the delay devices, so as to generate an output signal (100) at the output of the final delay device which is delayed with respect to the input signal by the desired time delay.

### CROSS-REFERENCE TO RELATED APPLICATIONS

This application claims the benefit of U.S. Provisional Patent Application No. 60/173,226, filed Dec. 28, 1999, which is assigned to the assignee of the present patent application and is incorporated herein by reference.

### FIELD OF THE INVENTION

The present invention relates generally to electronic timing circuitry, and specifically to delay generating circuitry.

### BACKGROUND OF THE INVENTION

A variable delay generator, as is known in the art, is designed to receive an input signal and output the identical signal after a desired delay. Typically, a variable delay generator consists of an array of individual (non-variable) delay stages and a selector, or multiplexer stage, which is used to select an amount of delay from the delays offered by the individual delay stages.

An undesired by-product caused by the multiplexer stage is a certain amount of unintended minimum delay. The “width” of a multiplexer (defined as the number of delay stages being multiplexed) is directly related to the unintended delay. For example, a series of 40 delay stages, which respectively generate a range of delays from 0.2-8.0 ns, may be coupled to a multiplexer, which adds an unintended delay of about 1 ns to the delay generated by each of the delays stages. The delay of the 0.2 ns stage and other short-delay stages is effectively masked by the delay added by the multiplexer. Thus, these prior art, large-width variable delay generators are not capable of producing small delays which may be desired for some applications.

In addition, when a delay generator operates on a train of pulses, each pulse may be distorted by the delay elements, typically by increasing the rise time and, to a smaller extent, the fall time of the pulse. For example, a delay generator may increase a pulse's rise time by 0.4 ns, but only increase the fall time by 0.1 ns. For some applications, the resultant asymmetric waveform may be improperly processed by circuitry to which it is conveyed, leading to data loss.

### SUMMARY OF THE INVENTION

It is an object of some aspects of the present invention to provide improved apparatus and methods for generating delay with an electronic circuit.

It is a further object of some aspects of the present invention to provide apparatus and methods for generating a selected amount of delay with an electronic circuit, while reducing the masking of small amounts of delay.

It is yet a further object of some aspects of the present invention to provide apparatus and methods for applying a delay to an input signal that do not substantially distort the symmetry of the signal.

In preferred embodiments of the present invention, a variable delay generator receives an input signal, which typically, but not necessarily, includes a series of regularly-spaced pulses, such as clock pulses. Preferably, a control unit coupled to the generator receives a delay selection signal, and responsive thereto, programs the delay generator to apply to the input signal an amount of delay specified by the selection signal. This programming typically comprises conveying selection control signals to a selection control array of the generator, and conveying delay control signals to a cascaded delay array of the generator. In regular operation of the variable delay generator, subsequent to the programming thereof, the selection control array conveys the input signal to one of a plurality of entry points of the delay array, whereby the input signal “cascades” through a number of components of the delay array, each step of the cascade adding a prescribed amount of delay to the signal. At the end of the cascade, the input signal, now delayed by the amount specified by the delay selection signal, is output from the delay array and from the variable delay generator.

Preferably, the selection control array and the delay array are configured so that small amounts of delay specified by the delay selection signal are not overshadowed by larger amounts of unintended delay, introduced by operation of the control unit, the cascaded delay array, or the selection control array. Preferred embodiments of the present invention pass the input signal substantially only through that portion of the selection array and the delay array required to generate the amount of delay selected, plus, at most, a small number of additional components (e.g., two).

Preferably, the selection array and the delay array are implemented using logic gates, which require only about 0.1 ns to change state. Thus, in some preferred embodiments of the present invention, the variable delay generator is able to apply delay to the input signal in increments as small as 0.1 ns, and, moreover, has a total overhead associated with the delay of not more than about 0.4 ns. Advantageously, this overhead is independent of the “width” of the variable delay generator (the number of possible delay increments which can be added to the input signal). The low total overhead, and the independence of the overhead on width, as provided by these embodiments of the present invention, are both in contrast to multiplexer-based programmable delay generators known in the art. These prior art devices, as described in the Background section of this application, add a minimum unintended delay of at least 1 ns for a multiplexer-width of 40 stages, and would add even more delay for a greater number of stages.

In some preferred embodiments of the invention, all of the components which add delay to the input signal introduce generally equal amounts of delay. Thus, by incrementally changing the delay selection signal, the total delay applied to the input signal increases in corresponding incremental steps. Alternatively, one or more buffers are placed in the path of the input signal, which, by virtue of their placement, increase the delay beyond that created by the components of the selection array and the delay array. For some applications, each buffer adds the same amount of delay as each of the other components (e.g., 0.1 ns). In other applications, each buffer adds its own amount of delay (e.g., 0.5, 1.0, or 1.5 ns). In this manner, for example, a circuit could be constructed to enable the delay selection signal to select among a large range of delays, for example:

0.2-4.0 ns, in steps of 0.1 ns,

5-20 ns, in steps of 0.5 ns, and

20-100 ns, in steps of 1 ns.

There is therefore provided, in accordance with a preferred embodiment of the present invention, apparatus for applying a delay to an input signal, including:

a plurality of delay devices, each having an input and an output, coupled in series such that the output of each of the delay devices, except for a final delay device in the series, is coupled to the input of a succeeding one of the delay devices in the series; and

a switching unit, adapted to receive a delay selection signal indicative of a desired time delay and, responsive thereto, to couple the input signal to the input of a designated one of the delay devices, so as to generate an output signal at the output of the final delay device which is delayed with respect to the input signal by the desired time delay.

Preferably, the apparatus includes an inverting gate, wherein the switching unit is adapted to couple the input signal to the inverting gate, responsive to the delay selection signal, such that in steady-state operation the output signal and the input signal have a common value. The input signal undergoes an even number of inversions due to operation of the delay devices and the inverting gate, so that a symmetry of the input signal is substantially preserved in the output signal.

Preferably, the switching unit is adapted to couple the input signal to the input of the final delay device, responsive to receiving a delay selection signal corresponding to a minimum desired delay, such that the final delay device is substantially the only one of the delay devices which adds delay to the input signal. Most preferably, the switching unit is adapted to couple the input signal to the input of the final delay device, such that the output signal generated at the output of the final delay device is delayed by a delay which is substantially independent of a total number of the delay devices. Additionally or alternatively, a first one of the delay devices is adapted to apply a first delay to a signal input through the input thereof, and a second one of the delay devices is adapted to apply to a signal input through the input thereof a second delay, which is different from the first delay.

In a preferred embodiment, the apparatus includes a delay element, which is adapted to add a delay to the input signal, wherein the switching unit is adapted to couple the input signal with the added delay to the input of the designated one of the delay devices.

Preferably, at least one of the delay devices includes at least one Boolean logic element, most preferably exactly one Boolean logic element. Further preferably, substantially every one of the delay devices include at least one Boolean logic element, wherein substantially every one of the delay devices includes exactly one Boolean logic element.

There is also provided, in accordance with a preferred embodiment of the present invention, a method for applying a delay to an input signal, including:

receiving a delay selection signal indicative of a desired time delay;

responsive to the selection signal, coupling the input signal in series to a designated number of delay devices; and

generating an output signal at a final one of the delay devices, which output signal is delayed with respect to the input signal by the desired time delay.

The present invention will be more fully understood from the following detailed description of the preferred embodiments thereof, taken together with the drawings, in which:

### BRIEF DESCRIPTION OF THE DRAWINGS

FIG. 1 is a block diagram of a delay generator, as is known in the art; and

FIG. 2 is a block diagram of a variable delay generator, in accordance with a preferred embodiment of the present invention.

### DETAILED DESCRIPTION OF PREFERRED EMBODIMENTS

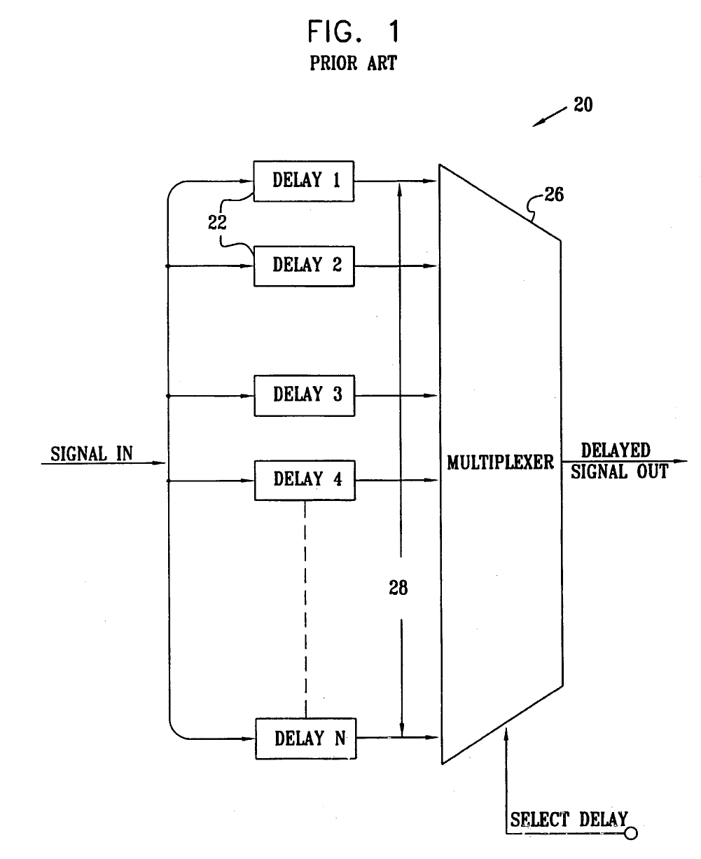

FIG. 1 is a block diagram of a delay generator 20, as is known in the art. Delay generator 20 comprises a parallel array of N delay units 22, each of which is coupled to receive an input signal, and to subsequently output the signal to a multiplexer 26, after a delay particular to each unit. In addition, a “select delay” signal is input to multiplexer 26, responsive to which multiplexer 26 selects and outputs the output of one of delay units 22. A disadvantage of this prior art delay generator is that, in addition to the planned delay added by the selected delay unit, operation of multiplexer 26, in and of itself, adds delay to the input signal. This multiplexer-based delay is dependent upon N, the “width” 28 of multiplexer 26. Thus, if multiplexer 26 is configured to select between a large number of delay units 22, then a significant amount of unwanted delay is added to the input signal.

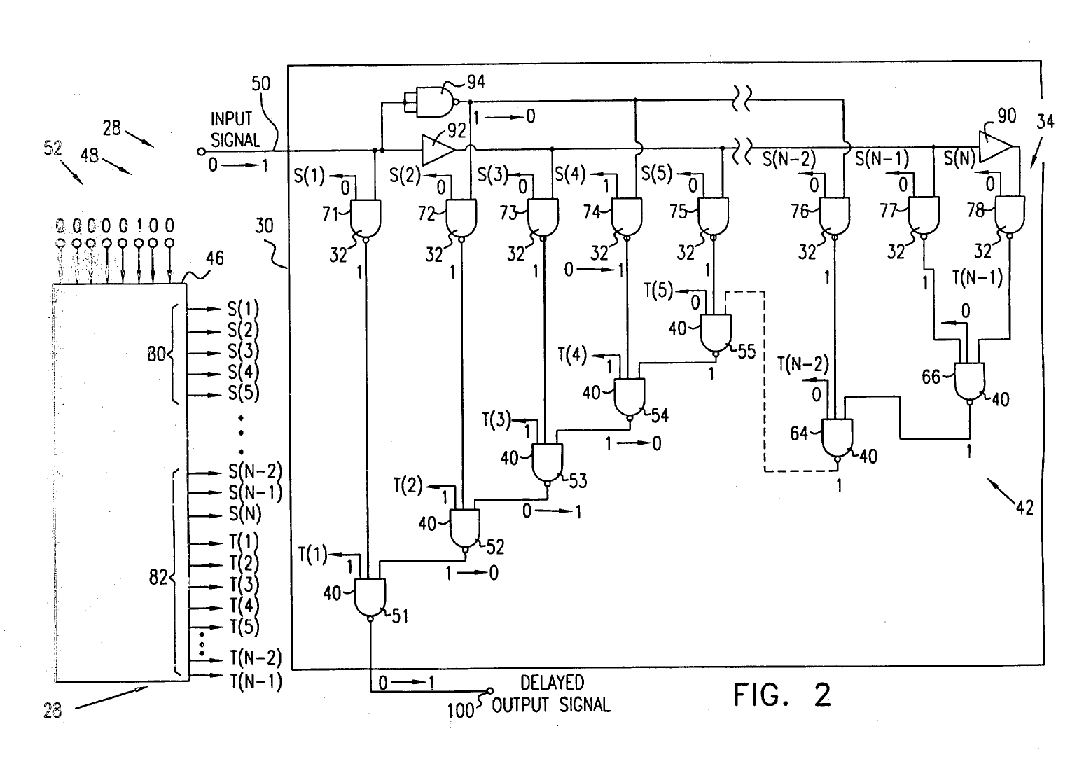

FIG. 2 is a block diagram of circuitry 28 for applying a selected delay to an input signal 50, in accordance with a preferred embodiment of the present invention. Preferably, circuitry 28 comprises a variable delay generator 30 and a control box 46 coupled thereto. The control box receives a delay selection signal D 52, and, responsive thereto, programs the delay generator to apply to the input signal an amount of delay specified by the selection signal. The delay is applied by controlling the number of devices through which the input signal passes prior to being output from the variable delay generator. To program variable delay generator 30, control box 46 preferably conveys selection control signals S(i) 80 to a selection control array 34 of the delay generator, and, additionally, conveys delay control signals T(i) 82 to a cascaded delay array 42 of delay generator 30.

Typically, delay selection signal D 52 comprises an 8-bit binary number, such as 0000 0100 (decimal 4), and is translated by control box 46 into the selection and delay control signals S(i) 80 and T(i) 82, in accordance with the following equations:

$$\begin{matrix}S ( i ) = \{ \begin{matrix}1 , i = D \\ 0 , i \neq D\end{matrix} \\ T ( i ) = \{ \begin{matrix}1 , i \leq D \\ 0 , i > D\end{matrix}\end{matrix}$$

For selection control signals S(i) 80, the index i varies from 1 to N, the number of increments of delay which can be selected by delay selection signal 52. For delay control signals T(i) 82, the index i varies from 1 to N−1. Thus, for example, if delay selection signal D 52 is set to 4, (binary 0000 0100, as shown in FIG. 2), then S(4)=1, S(i≠4)=0, T(1?i?4)=1, and T(i>4)=0.

Preferably, selection control array 34 comprises a plurality of selector control devices 32, exactly one of which is selected by delay selection signal 52 to have its output vary with changes of input signal 50, as described hereinbelow. The output of the remainder of the selector control devices preferably remains in a constant state, independent of the input signal. To enable this selection of a particular one of selector control devices 32, each one of these devices—selector control(1) 71, selector control(2) 72, selector control(3) 73, selector control(4) 74, selector control(5) 75, selector control(N−2) 76, selector control(N−1) 77 and selector control(N) 78—is coupled to receive as inputs thereto a respective one of selection control signals 80, as shown in FIG. 2.

Preferably, each of selector control devices 32 comprises a NAND logic gate, having as inputs thereto a respective one of selection control signals S(−) 80 and a signal that changes state responsive to input signal 50, as described hereinbelow. For example, selector control(4) 74 has one input which conveys S(4) from control box 46, and a second input which conveys the inverse of input signal 50, preferably as inverted by a NAND gate 94 configured to operate as a NOT gate. Thus, for the entire time that delay selection signal D 52 is set to 4, selector control(4) 74 receives as inputs a steady-state 1 from selection control signal S(4) and the inverse of input signal 50. Consequently, as input signal 50 transitions from 0 to 1 (as shown by the “0>1” in FIG. 2), the output of NAND gate 94 changes from 1 to 0, and the output of selector control(4) 74 changes from 0 to 1. (All of the steady-state and alternating values shown in FIG. 2 are for the example of delay selection signal D 52 being set to 4). For all selector control devices 32 other than selector control(4) 74, the steady-state selection control signals being input thereto are 0, so their steady-state output is 1, regardless of the value of input signal 50. (An input of even a single 0 to a NAND gate determines that the gate's output is 1.)

Cascaded delay array 42 of delay generator 30 preferably comprises a plurality of delay devices 40, each comprising a 3-input NAND logic gate. Each of delay devices 40 shown in FIG. 2—delay(1) 51, delay(2) 52, delay(3) 53, delay(4) 54, delay(5) 55, delay(N−2) 64 and delay(N−1) 66—is typically coupled to receive a first input comprising one of delay control signals T(i) 82, a second input from a respective one of selector control devices 32, and a third input from the output of the delay device to its right, as shown in FIG. 2.

When, for example, delay selection signal 52 is set to 4, then S(4)=1, delay control signals 82 T(1) through T(4) are steady-state 1's, and delay control signals T(5) through T(N−1) are steady-state 0's. Such a steady-state 0 input to each delay device 40 to the right of delay(4) 54 in FIG. 2 insures a steady-state output therefrom of 1, regardless of the state of input signal 50. Thus, it is noted that even though the state of each of the delay devices in cascaded delay array 42 would appear to depend on the output of each of the delay devices to its right in FIG. 2, delay control signals T(i) 82 effectively “cut off” all of the delay devices for which the delay control signal input thereto is 0 (namely, delay(5) 55, delay(N−2) 64, and delay(N−1) in the example), by forcing their output to be a steady-state 1, rather than a function of input signal 50. In this manner, as will be described in detail hereinbelow, variable delay generator 30 channels input signal 50 through a selected number of logic gates, in order to add a desired amount of delay to the input signal prior to its output from variable delay generator 30. Thus, in effect, control box 46 and selection control array 34 perform the functions of a switching unit 48, which controls the coupling of input signal 50 to a desired one of the delay devices, thereby regulating the amount of delay added to the input signal.

Unlike the delay devices to the right of delay(4) 54, delay(4) itself receives a steady-state input of 1 from delay control signal T(4). In addition, because the input it receives from delay(5) 55 is also a steady-state 1, the output of delay(4) 54 is the inverse of its third input (according to the rule governing a 3-input NAND gate). This third input is the output of selector control(4) 74, which changes state responsive to each change of state of input signal 50. Therefore, the output of delay(4) 54 changes upon each change of input signal 50. Subsequently, this change of state propagates through delay array 42, because the delay control signals input to delay(1) 51, delay(2) 52 and delay(3) 53 are steady-state 1's, and the outputs of selector control(1) 71, selector control(2) 72 and selector control(3) 73 are also steady-state 1's, as described hereinabove. Thus, the signal cascades, in order, through delay(4) 54, delay(3) 53, delay(2) 52, and delay(1) 51, being inverted as it passes through each delay device, until it leaves variable delay generator 30 as a delayed output signal 100. At this point, output signal 100 corresponds to an appropriately-delayed image of input signal 50, because circuit 28 is preferably configured to invert the input signal an even number of times, regardless of the path which the input signal takes through the circuit. The use of an even number of inversions also ensures that the output signal will be substantially symmetrical, without relative distortion of the rise and fall times of the signal.

The inherent delay of a single delay device 40 is typically about 0.1 ns. Preferably, but not necessarily, each delay device 40 adds a delay of substantially equal length to the propagation of input signal 50 through variable delay generator 30. In a preferred embodiment, however, at least one of the delay devices applies a delay to the signal which is different from that applied by another one of the delay devices.

For the configuration of FIG. 2, the minimal delay path is obtained by choosing selector control(1) 71. This path causes input signal 50 to pass through two logic gates, selector control(1) 71 and delay(1) 51, yielding a total added delay of no more than about 0.4 ns. It is noted that prior art delay generators, such as delay generator 20, described hereinabove with reference to FIG. 1, are generally unable to produce such a small delay when they incorporate large-width multiplexers, because of the inherent delay added to the input signal by passing through the multiplexer, even when the shortest delay is selected. Variable delay generator 30, by contrast, is configured so that selected small delays are not overshadowed by the width of selection array 34.

Alternatively, if selector control(2) 72 is chosen, then the signal propagation path includes NAND gate 94, selector control(2) 72, delay(2) 52 and delay(1) 51, yielding a total added delay of 0.8 ns. It will be appreciated that increases of the delay in increments of 2 ns can be obtained by selecting an appropriate one of selector control devices 32.

It will be seen that input signal 50 is transmitted through NAND gate 94 only to alternating ones of selector control devices 32. The inclusion of NAND gate 94 in propagation paths which would otherwise comprise an odd number of inversions of input signal 50 provides an even number of inversions of the input signal as it passes through variable delay generator 30. The even number of inversions generally assures that in the steady state, delayed output signal 100 will be in the same state as input signal 50, and that when the input signal is alternating between states, the Boolean value of the delayed output signal will track the value of the input signal, after the selected delay.

Additionally, it is noted that providing an even number of NAND gates in the propagation path of input signal 50 minimizes changes to the input signal's duty cycle. In an ideal pulse, the rise time to the high phase and the fall time to the low phase are zero. Prior art delay generators tend to increase the rise time and the fall time of pulses asymmetrically, thereby undesirably modifying the input signal's duty cycle. According to embodiments of the present invention in which the input signal is inverted an even number of times, however, the effect on the duty cycle of the input signal is minimized.

Preferably, a buffer 92 comprising a simple (non-inverting) logic gate is included in the propagation path of input signal 50 to selector control(3) 73, selector control(5) 75, and, similarly, every selector control device 32 which does not receive the output of NAND gate 94. As shown in FIG. 2, each propagation path which receives the output of buffer 92 includes an even number of inverting logic gates. Consequently, buffer 92 is non-inverting—unlike NAND gate 94 which inverts the input signal prior to its passage through an odd number of inverting logic gates. Preferably, buffer 92 has a delay associated therewith, e.g., 2 ns, which is substantially the same as that induced by each of the other logic gates described hereinabove, such that by steadily incrementing the value of delay selection signal 52, a corresponding regular increase in the amount of applied delay will be obtained, regardless of whether the input signal passes through NAND gate 94 or buffer 92.

In additional non-inverting buffer 90 and other optional buffers (not shown) placed in the propagation path of input signal 50, are typically used to add particular quantities of delay which are different from that provided by the other logic gates described hereinabove. For example, buffer 90 may be configured to add, in and of itself, 30 ns of delay to the input signal when it passes therethrough. By proper placement of appropriate buffers in the propagation path, a broad spectrum of delays can be obtained, with increments generally ranging from about 2 ns to substantially any value which is suitable for a given task. Thus, for example, this embodiment of the present invention could be used to allow the selection of any of the following delays: 4 ns, 8 ns, 10 ns, 12 ns, 14 ns, 20 ns, 50 ns and 100 ns.

It will be appreciated that the preferred embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description, and which are not disclosed in the prior art.

1. Apparatus for applying a delay to an input signal, comprising:
a plurality of delay devices, each having an input and an output, coupled in series such that the output of each of the delay devices, except for a final delay device in the series, is coupled to the input of a succeeding one of the delay devices in the series; and
a switching unit, adapted to receive a delay selection signal indicative of a desired time delay and, responsive thereto, to couple the input signal to the input of a designated one of the delay devices, so as to generate an output signal at the output of the final delay device which is delayed with respect to the input signal by the desired time delay.

2. Apparatus according to claim 1, and comprising an inverting gate, wherein the switching unit is adapted to couple the input signal to the inverting gate, responsive to the delay selection signal, such that in steady-state operation the output signal and the input signal have a common value.

3. Apparatus according to claim 2, wherein the input signal undergoes an even number of inversions due to operation of the delay devices and the inverting gate, so that a symmetry of the input signal is substantially preserved in the output signal.

4. Apparatus according to claim 1, wherein the switching unit is adapted to couple the input signal to the input of the final delay device, responsive to receiving a delay selection signal corresponding to a minimum desired delay, such that the final delay device is substantially the only one of the delay devices which adds delay to the input signal.

5. Apparatus according to claim 4, wherein the switching unit is adapted to couple the input signal to the input of the final delay device, such that the output signal generated at the output of the final delay device is delayed by a delay which is substantially independent of a total number of the delay devices.

6. Apparatus according to any of claims 1-5, wherein a first one of the delay devices is adapted to apply a first delay to a signal input through the input thereof, and wherein a second one of the delay devices is adapted to apply to a signal input through the input thereof a second delay, which is different from the first delay.

7. Apparatus according to any of claims 1-5, and comprising a delay element, which is adapted to add a delay to the input signal, wherein the switching unit is adapted to couple the input signal with the added delay to the input of the designated one of the delay devices.

8. Apparatus according to any of claims 1-5, wherein at least one of the delay devices comprises at least one Boolean logic element.

9. Apparatus according to claim 8, wherein the at least one Boolean logic element comprises exactly one Boolean logic element.

10. Apparatus according to claim 8, wherein substantially every one of the delay devices comprises at least one Boolean logic element.

11. Apparatus according to claim 10, wherein substantially every one of the delay devices comprise exactly one Boolean logic element.

12. A method for applying a delay to an input signal, comprising:
receiving a delay selection signal indicative of a desired time delay;
responsive to the selection signal, coupling the input signal in series to a designated number of delay devices; and
generating an output signal at a final one of the delay devices, which output signal is delayed with respect to the input signal by the desired time delay.

13. A method according to claim 12, wherein coupling the input signal comprises inverting the input signal by an inverting gate which is not one of the delay devices, such that in steady-state operation the output signal and the input signal have a common value.

14. A method according to claim 13, wherein generating the output signal comprises applying an even number of inversions to the input signal, so that a symmetry of the input signal is substantially preserved in the output signal.

15. A method according to any of claims 12-14, wherein coupling the input signal comprises coupling the input signal to the final one of the delay devices, responsive to receiving a delay selection signal corresponding to a minimum desired delay, such that the final delay device is substantially the only one of the delay devices which adds delay to the input signal.

16. A method according to claim 15, wherein coupling the input signal to the delay devices comprises applying a first delay at a first one of the devices, and applying at a second one of the devices a second delay, which is different from the first delay.

17. A method according to claim 15, and comprising adding a designated delay to the input signal prior to coupling the signal to the delay devices.
